(19) United States
(12) Patent Application Publication
(10) Pub. No.: US 2024/0128155 A1
(43) Pub. Date: Apr. 18, 2024

(54) SEMICONDUCTOR PACKAGE AND METHOD OF MANUFACTURING THE SAME

(71) Applicant: Samsung Electronics Co., Ltd., Suwon-si (KR)

(72) Inventors: Minjun Bae, Suwon-si (KR); Eungkyu Kim, Suwon-si (KR); Jongyoun Kim, Suwon-si (KR)

(21) Appl. No.: 18/379,841

(22) Filed: Oct. 13, 2023

(30) Foreign Application Priority Data
Oct. 14, 2022 (KR) 10-2022-0132719

(51) Int. Cl. H01L 23/373; H01L 21/56; H01L 23/00; H01L 23/31; H01L 23/367; H01L 23/498; H01L 25/065; H10B 80/00

(52) U.S. Cl. CPC H01L 23/3738; H01L 21/565; H01L 23/3107; H01L 23/367; H01L 23/49822; H01L 23/49838; H01L 24/16; H01L 24/32; H01L 24/73; H01L 24/83; H01L 25/0655; H10B 80/00; H01L 2224/16227; H01L 2224/16238; H01L 2224/32225; H01L 2224/73253; H01L 2224/83896; H01L 2924/1431; H01L 2924/1436; H01L 2924/1437; H01L 2924/1441

(57) ABSTRACT

Provided is a semiconductor package comprising a redistribution structure including a redistribution pattern and a redistribution insulation layer covering the redistribution pattern, a semiconductor chip disposed on the redistribution structure and having an active surface and an inactive surface opposite to the active surface, a molding layer disposed on the redistribution structure and covering at least a portion of the semiconductor chip, and a silicon heat dissipation structure disposed on the semiconductor chip, wherein the silicon heat dissipation structure is bonded to the semiconductor chip through silicon (Si)-to-Si direct bonding.

### CROSS-REFERENCE TO RELATED APPLICATION

This application is based on and claims priority under 35 U.S.C. § 119 to Korean Patent Application No. 10-2022-0132719, filed on Oct. 14, 2022, in the Korean Intellectual Property Office, the disclosure of which is incorporated by reference herein in its entirety.

### BACKGROUND

Aspects of the inventive concept relate to a semiconductor package and a method of manufacturing the same, and more particularly, to a semiconductor package including a redistribution structure and a method of manufacturing the same.

According to the development of the electronics industry and the needs of users, semiconductor packages included in electronic products are demanded to include various functions and provide high performance. Therefore, a semiconductor package including a plurality of semiconductor chips has been proposed. Meanwhile, as a semiconductor package includes a plurality of semiconductor chips, a method of effectively dissipating heat generated from the plurality of semiconductor chips is demanded.

### SUMMARY

Aspect of the inventive concept provide a semiconductor package that may exhibit improved heat dissipation efficiency and be manufactured through a simplified process and a method of manufacturing the same.

According to an aspect of the inventive concept, there is provided a semiconductor package including a redistribution structure including a redistribution pattern and a redistribution insulation layer covering the redistribution pattern, a semiconductor chip disposed on the redistribution structure and having an active surface and an inactive surface opposite to the active surface, a molding layer disposed on the redistribution structure and covering at least a portion of the semiconductor chip, and a silicon heat dissipation structure disposed on the semiconductor chip, wherein the silicon heat dissipation structure is bonded to the semiconductor chip through silicon (Si)-to-Si direct bonding.

According to another aspect of the inventive concept, there is provided a semiconductor package including a package substrate, a redistribution structure disposed on the package substrate and including a redistribution pattern and a redistribution insulation layer covering the redistribution pattern, a first semiconductor chip disposed on the redistribution structure and having a first active surface and a first inactive surface opposite to the first active surface, a second semiconductor chip disposed on the redistribution structure and having a second active surface and a second inactive surface opposite to the second active surface, a molding layer disposed on the redistribution structure and covering at least a portion of the first semiconductor chip and at least a portion of the second semiconductor chip, and a silicon heat dissipation structure disposed on the first semiconductor chip and the second semiconductor chip, wherein the silicon heat dissipation structure is bonded to the first semiconductor chip and the second semiconductor chip through silicon (Si)-to-Si direct bonding.

According to another aspect of the inventive concept, there is provided a semiconductor package including a redistribution structure including a redistribution pattern and a redistribution insulation layer covering the redistribution pattern, a semiconductor chip disposed on the redistribution structure and having an active surface and an inactive surface opposite to the active surface, wherein the inactive surface is hydrophilized, a molding layer disposed on the redistribution structure and covering at least a portion of the semiconductor chip, and a silicon heat dissipation structure disposed on the semiconductor chip, wherein the silicon heat dissipation structure is bonded to the semiconductor chip through silicon-to-silicon direct bonding.

According to another aspect of the inventive concept, there is provided a method of manufacturing a semiconductor package, the method including forming a redistribution structure on a support substrate, mounting a semiconductor chip on the redistribution structure, forming a molding layer covering the semiconductor chip on the redistribution structure, planarizing the molding layer, forming a silicon heat dissipation structure by hydrophilizing a bottom surface of a bare silicon wafer, providing the silicon heat dissipation structure on the semiconductor chip, and bonding the semiconductor chip and the silicon heat dissipation structure to each other, wherein the semiconductor chip and the silicon heat dissipation structure bonded to each other through silicon-to-silicon direct bonding.

### BRIEF DESCRIPTION OF THE DRAWINGS

Embodiments of the inventive concept will be more clearly understood from the following detailed description taken in conjunction with the accompanying drawings in which:

FIG. 1A is a cross-sectional view of a semiconductor package according to embodiments;

FIG. 1B is an enlarged cross-sectional view of a portion EX of FIG. 1A;

FIG. 2 is a cross-sectional view of a semiconductor package according to an embodiment;

FIG. 3A is a cross-sectional view of a semiconductor package according to an embodiment;

FIG. 3B is a cross-sectional view of a semiconductor package according to an embodiment;

FIG. 4 is a flowchart schematically illustrating a method of manufacturing a semiconductor package, according to embodiments; and

FIGS. 5A to 5H are cross-sectional views showing respective operations of a method of manufacturing a semiconductor package, according to embodiments.

### DETAILED DESCRIPTION OF THE EMBODIMENTS

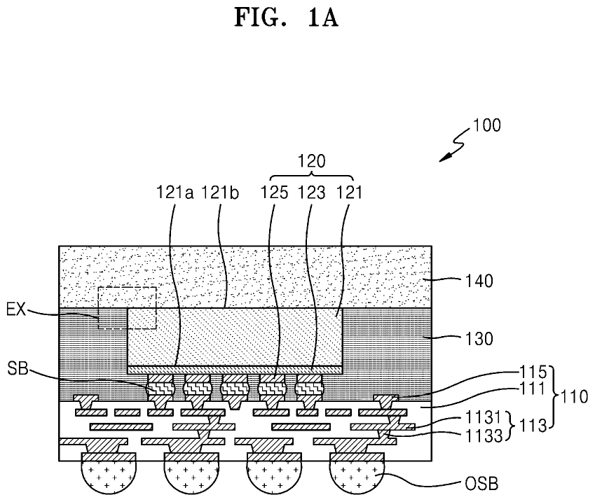

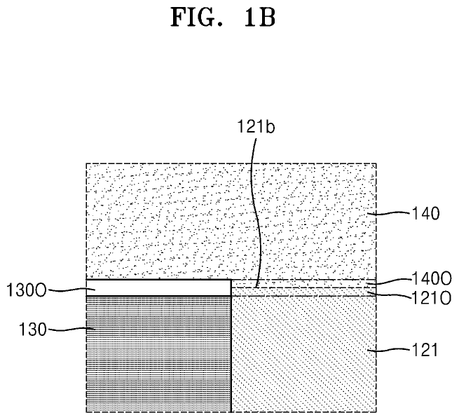

FIG. 1A is a cross-sectional view of a semiconductor package 100 according to embodiments.

Referring to FIG. 1A, the semiconductor package 100 may include a redistribution structure 110, a semiconductor chip 120, a molding layer 130, and a silicon heat dissipation structure 140.

The redistribution structure 110 may be a substrate on which the semiconductor chip 120 is mounted. According to an embodiment, the redistribution structure 110 may be a redistribution interposer. The redistribution structure 110 may include a redistribution insulation layer 111 and a redistribution pattern 113. Hereinafter, unless specified otherwise, a direction parallel to the top surface of the redistribution structure 110 is defined as a horizontal direction (i.e., the X direction and the Y direction), and a direction perpendicular to the top surface of the redistribution structure 110 is defined as a vertical direction (i.e., the Z direction).

The redistribution insulation layer 111 may cover the redistribution pattern 113. The redistribution insulation layer 111 may include a plurality of insulation layers stacked in a vertical direction or may include a single insulation layer. The redistribution insulation layer 111 may include, for example, photo imageable dielectric (PID) or photosensitive polyimide (PSPI).

The redistribution pattern 113 may include a plurality of redistribution lines 1131 extending in a horizontal direction and a plurality of redistribution vias 1133 extending at least partially through the redistribution insulation layer 111. The plurality of redistribution lines 1131 may extend in a horizontal direction along at least one of the top surface and the bottom surface of each of the insulation layers constituting the redistribution insulation layer 111. Here, at least some of the plurality of redistribution lines 1131 may be at a different vertical level from the other redistribution lines 1131. The plurality of redistribution vias 1133 may electrically interconnect to one another the plurality of redistribution lines 1131 that are at different vertical levels.

According to an embodiment, the plurality of redistribution vias 1133 may have a tapered shape that a horizontal width thereof decreases as the distance from the semiconductor chip 120 increases. This shape may be because the semiconductor package 100 is manufactured in a chip-last method.

According to an embodiment, the redistribution pattern 113 may include a metal like copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), and ruthenium (Ru), or an alloy thereof. The redistribution structure 110 may include a plurality of redistribution pads 115 disposed at the top of the redistribution pattern 113. The plurality of redistribution pads 115 may protrude from the uppermost redistribution insulation layer 111.

The semiconductor chip 120 may be disposed on the redistribution structure 110. According to an embodiment, the semiconductor chip 120 may be a memory chip or a logic chip. The memory chip may be, for example, a volatile memory chip like dynamic random access memory (DRAM) or static random access memory (SRAM) or a non-volatile memory chip like phase-change random access memory (PRAM), magneto-resistive random access memory (MRAM), ferroelectric random access memory (FeRAM), or resistive random access memory (RRAM). Also, the logic chip may be, for example, a microprocessor, an analog device, or a digital signal processor. The semiconductor chip 120 may include a semiconductor substrate 121, an active layer 123, and a chip pad 125.

The semiconductor substrate 121 may include an active surface 121a and an inactive surface 121b opposite to each other. The active surface 121a of the semiconductor substrate 121 may correspond to the bottom surface of the semiconductor substrate 121 facing the redistribution structure 110, and the inactive surface 121b of the semiconductor substrate 121 may correspond to the top surface of the semiconductor substrate 121 facing the silicon heat dissipation structure 140.

The semiconductor substrate 121 may include a semiconductor wafer. In an example embodiment, the semiconductor substrate 121 may include silicon (Si). For example, the semiconductor substrate 121 may include a silicon semiconductor or a compound semiconductor including silicon like silicon-germanium (Si—Ge). Since the semiconductor substrate 121 includes silicon, the semiconductor substrate 121 may be connected to the silicon heat dissipation structure 140 to be described later through a silicon-to-silicon direct bonding method. The semiconductor substrate 121 may include a conductive region, e.g., a well doped with an impurity. The semiconductor substrate 121 may have various device isolation structures like a shallow trench isolation (STI) structure.

The active layer 123 may be formed on an active surface 121a of the semiconductor substrate 121. The active layer 123 may include individual devices like circuit patterns and transistors. The active layer 123 may include a front end of line (FEOL) structure (not shown) disposed on the active surface 121a of the semiconductor substrate 121 and a back end of line (BEOL) structure (not shown) disposed on the FEOL structure.

The FEOL structure may include a plurality of individual devices of various types. The individual devices may include various microelectronic devices, e.g., a metal-oxide-semiconductor field effect transistor (MOSFET) like a complementary metal-oxide semiconductor (CMOS) transistor, a system large scale integration (LSI), an image sensor like a CMOS imaging sensor (CIS), a micro-electro-mechanical system (MEMS), an active device, a passive device, etc. The plurality of individual devices may be electrically connected to the conductive region of the semiconductor substrate 121. The plurality of individual devices may each be electrically separated from other neighboring individual devices by an insulation layer (not shown).

The BEOL structure may be disposed on the FEOL structure. The horizontal width of the BEOL structure may be the same as the horizontal width of the FEOL structure and the horizontal width of the semiconductor substrate 121. The BEOL structure may be electrically connected to a plurality of individual devices included in the FEOL structure and the conductive region of the semiconductor substrate 121. Terms such as “same,” “equal,” “identical,” “planar,” or “coplanar,” as used herein when referring to orientation, layout, location, shapes, sizes, compositions, amounts, or other measures do not necessarily mean an exactly identical orientation, layout, location, shape, size, composition, amount, or other measure, but are intended to encompass nearly identical orientation, layout, location, shapes, sizes, compositions, amounts, or other measures within acceptable variations that may occur, for example, due to manufacturing processes. The term “substantially” may be used herein to emphasize this meaning, unless the context or other statements indicate otherwise. For example, items described as “substantially the same,” “substantially equal,” or “substantially planar,” may be exactly the same, equal, or planar, or may be the same, equal, or planar within acceptable variations that may occur, for example, due to manufacturing processes.

A connection terminal SB may be provided between the semiconductor chip 120 and the redistribution structure 110. The connection terminal SB may contact the chip pad 125 of the semiconductor chip 120 and a redistribution pad 115 of the redistribution structure 110, thereby physically and electrically interconnecting the semiconductor chip 120 to the redistribution structure 110. The connection terminal SB may include, for example, at least one of solder, tin (Sn), silver (Ag), copper (Cu), and aluminum (Al). It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” or “contact” to another element, there are no intervening elements present at the point of contact.

The molding layer 130 is disposed on the redistribution structure 110 and may cover at least a portion of the semiconductor chip 120. According to an embodiment, the molding layer 130 may extend along the bottom surface and both sidewalls of the semiconductor chip 120, and the top surface of the molding layer 130 may be coplanar with the top surface (e.g., inactive surface) of the semiconductor chip 120.

According to an embodiment, the molding layer 130 may include an insulating polymer or an epoxy resin. For example, the molding layer 130 may include an epoxy molding compound (EMC).

The silicon heat dissipation structure 140 may be disposed on the semiconductor chip 120. According to an embodiment, the horizontal width of the silicon heat dissipation structure 140 may be the same as the horizontal width of the redistribution structure 110. Therefore, the silicon heat dissipation structure 140 may be disposed not only on the semiconductor chip 120 but also on the molding layer 130.

According to an embodiment, the silicon heat dissipation structure 140 may be formed by being processed from a bare silicon wafer. According to an embodiment, the thickness of the silicon heat dissipation structure 140 may be from about 10 μm to about 755 μm. Hereinafter, a thickness is defined as a length in a vertical direction.

Hereinafter, the connection between the silicon heat dissipation structure 140 and the semiconductor chip 120 is described in more detail with reference to FIG. 1B.

FIG. 1B is an enlarged cross-sectional view of a portion EX of FIG. 1A.

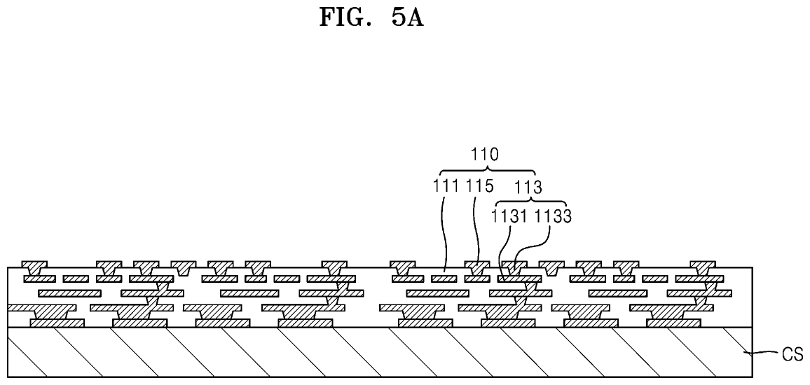

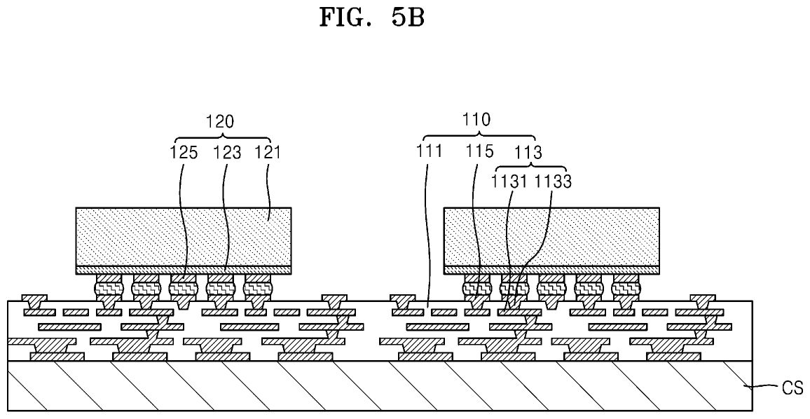

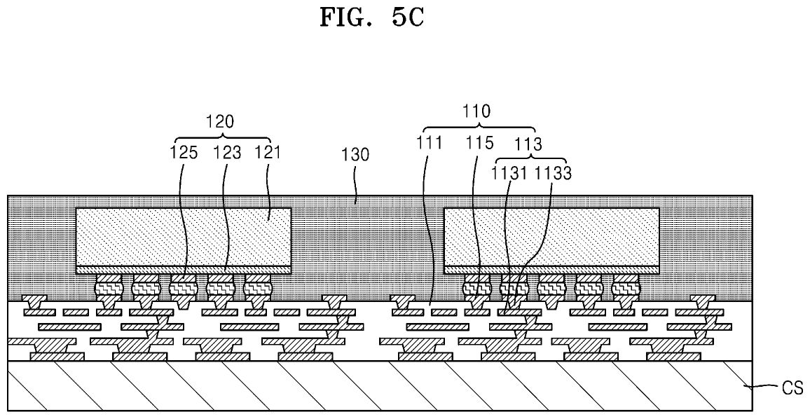

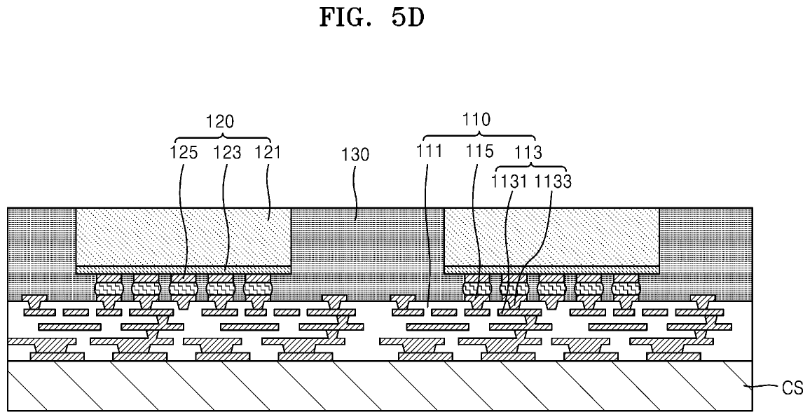

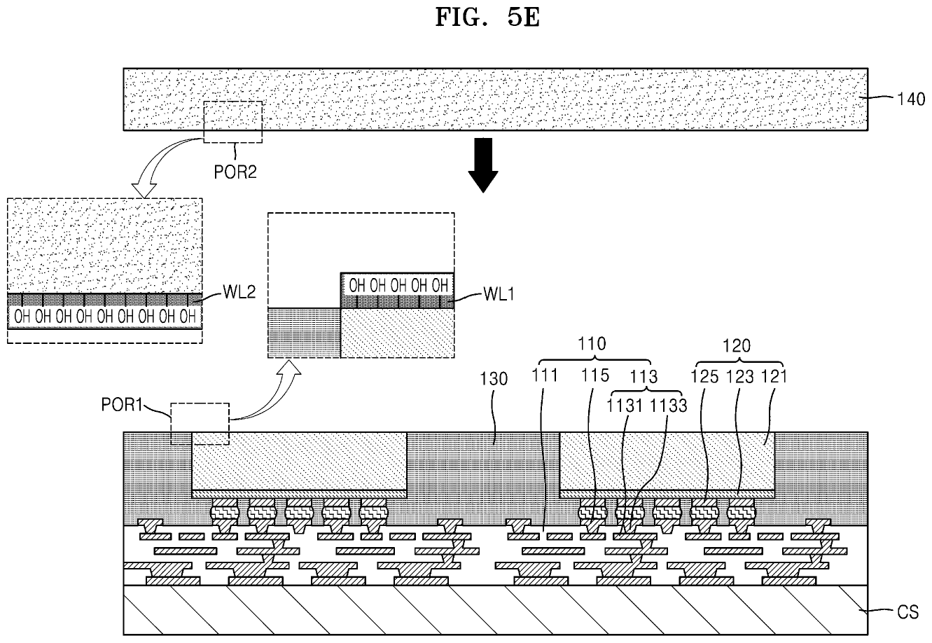

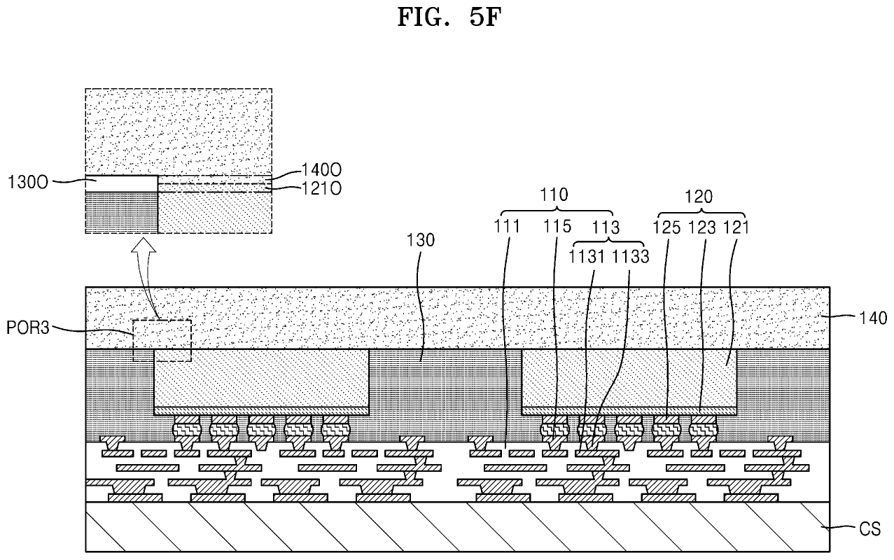

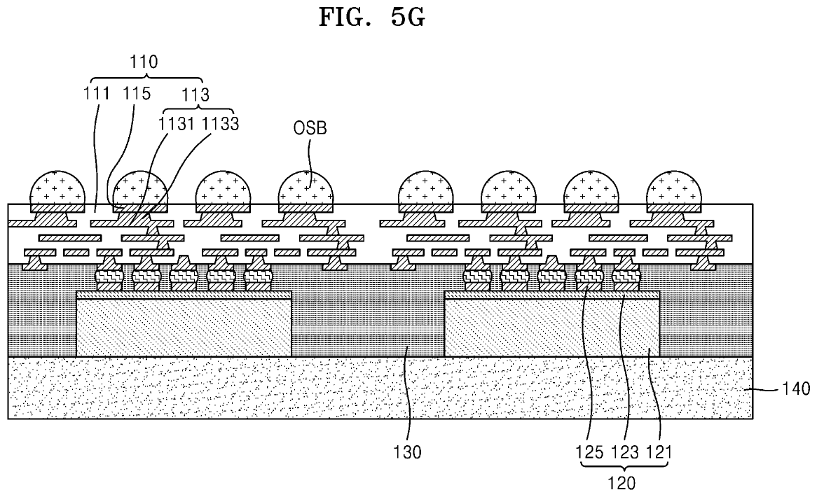

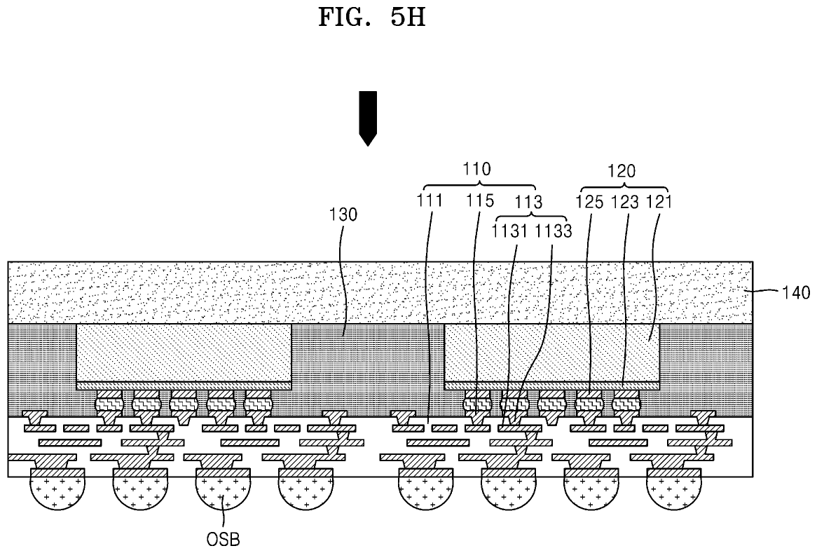

Referring to FIG. 1B, the semiconductor chip 120 may include a first oxide layer 121O adjacent to an interface where the silicon heat dissipation structure 140 and the semiconductor chip 120 come into contact on the top surface of the semiconductor substrate 121, and the silicon heat dissipation structure 140 may have a second oxide layer 140O adjacent to an interface where the silicon heat dissipation structure 140 and the semiconductor chip 120 come into contact on the bottom surface of the silicon heat dissipation structure 140. For convenience of explanation, FIG. 1B shows that the first oxide layer 121O and the second oxide layer 140O are separate layers. However, the first oxide layer 121O and the second oxide layer 140O may be integrally formed as a single oxide layer. In other words, an oxide layer including the first oxide layer 121O and the second oxide layer 140O may be provided between the semiconductor chip 120 and the silicon heat dissipation structure 140. According to an embodiment, the first oxide layer 121O and the second oxide layer 140O may include a silicon-oxygen-silicon (Si—O—Si) bond. The Si—O—Si bond may be formed at the interface between the silicon heat dissipation structure 140 and the semiconductor chip 120 as the silicon heat dissipation structure 140 having a hydrophilized bottom surface is connected to the semiconductor chip 120, as described below with reference to FIGS. 5E and 5F. Due to the Si—O—Si included in the first oxide layer 121O and the second oxide layer 140O, the silicon heat dissipation structure 140 and the semiconductor chip 120 may be bonded through silicon-to-silicon direct bonding without a separate adhesive layer.

On the other hand, the molding layer 130 may not include silicon. Therefore, an air layer 130O is provided between the molding layer 130 and the silicon heat dissipation structure 140, and, due to the existence of the air layer 130O, the molding layer 130 and the silicon heat dissipation structure 140 may not be connected to each other through silicon-to-silicon direct bonding. Here, the air layer 130O is defined as a layer including vacuum or air.

Referring back to FIG. 1A, the semiconductor package 100 may further include a plurality of external connection terminals OSB. The plurality of external connection terminals OSB may be arranged on the bottom surface of the redistribution structure 110. Some of the plurality of external connection terminals OSB may be arranged to overlap the semiconductor chip 120 in a vertical direction, and the other external connection terminals OSB may be arranged to not to overlap the semiconductor chip 120 in the vertical direction. An external connection terminal OSB may include, for example, solder. The external connection terminal OSB may physically and electrically interconnect an external device to the semiconductor package 100.

The semiconductor package 100 according to an embodiment is disposed on the semiconductor chip 120 and includes the silicon heat dissipation structure 140 that is bonded to the semiconductor chip 120 through silicon-to-silicon direct bonding. Therefore, heat generated due to the operation of the semiconductor chip 120 may be better dissipated than a case where a separate adhesive layer is included. Therefore, heat dissipation characteristics of the semiconductor package 100 including the same may be improved.

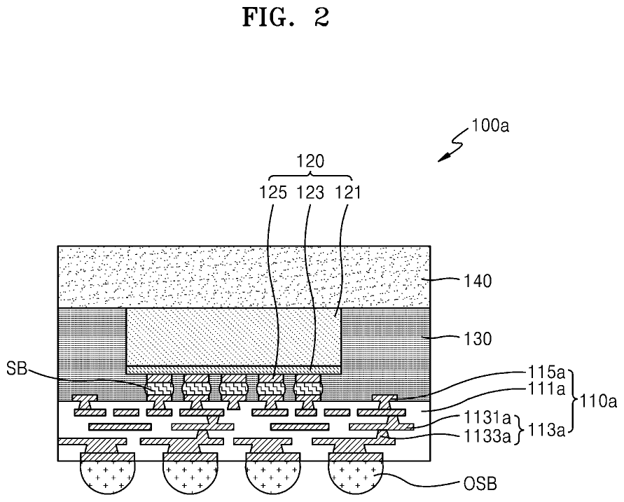

FIG. 2 is a cross-sectional view of a semiconductor package 100a according to an embodiment. Since components of the semiconductor package 100a shown in FIG. 2 are similar to the components of the semiconductor package 100 described above with reference to FIG. 1A, descriptions below focus on the differences therebetween.

Referring to FIG. 2, the semiconductor package 100a may include a redistribution structure 110a, the semiconductor chip 120, the molding layer 130, and the silicon heat dissipation structure 140.

The redistribution structure 110a may be a substrate on which the semiconductor chip 120 is mounted. According to an embodiment, the redistribution structure 110a may be a redistribution interposer. The redistribution structure 110a may include a redistribution insulation layer 111a and a redistribution pattern 113a.

The redistribution insulation layer 111a may cover the redistribution pattern 113a. The redistribution insulation layer 111a may include a plurality of insulation layers stacked in a vertical direction or may include a single insulation layer. The redistribution insulation layer 111a may include a material that is substantially the same as or similar to the material constituting the redistribution insulation layer 111 described above with reference to FIG. 1A.

The redistribution pattern 113a may include a plurality of redistribution lines 1131a extending in a horizontal direction and a plurality of redistribution vias 1133a extending at least partially through the redistribution insulation layer 111a.

According to an embodiment, the plurality of redistribution vias 1133a may have a tapered shape such that a horizontal width thereof increases as the distance from the semiconductor chip 120 increases in the vertical direction. This shape may be because the semiconductor package 100a is manufactured in a chip-first method.

The redistribution pattern 113a may include a material that is substantially the same as or similar to the material constituting the redistribution pattern 113 described above with reference to FIG. 1A. The redistribution structure 110a may include a plurality of redistribution pads 115a disposed at the top of the redistribution pattern 113a.

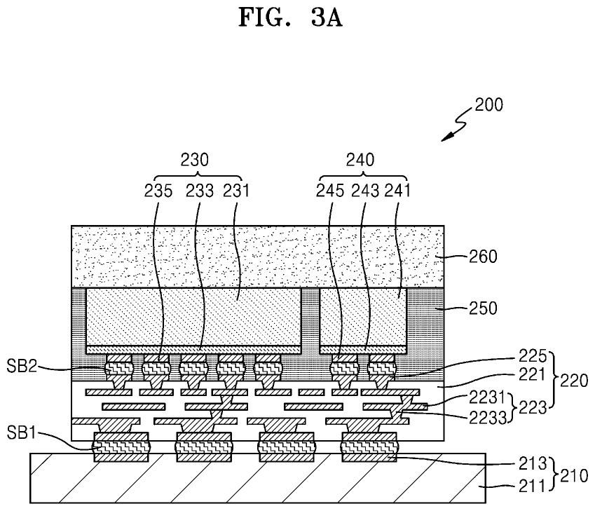

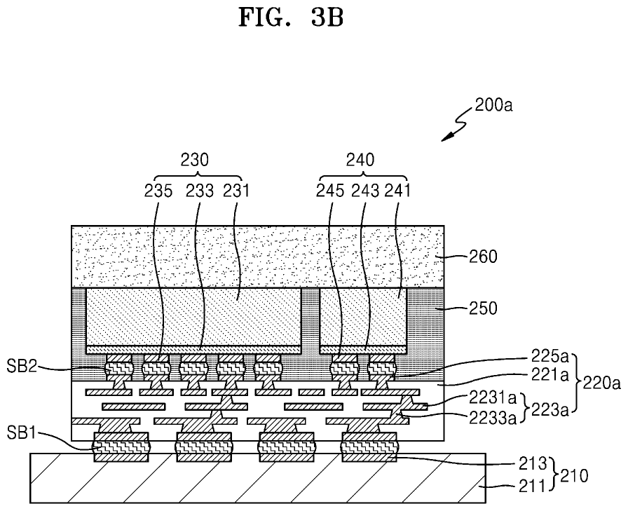

FIG. 3A is a cross-sectional view of a semiconductor package 200 according to an embodiment.

Referring to FIG. 3A, the semiconductor package 200 may include a package substrate 210, a redistribution structure 220, a first semiconductor chip 230, a second semiconductor chip 240, a molding layer 250, and a silicon heat dissipation structure 260.

The package substrate 210 may be a printed circuit board. For example, the package substrate 210 may be a multi-layer printed circuit board. The package substrate 210 may include a substrate base 211 and a substrate pad 213.

The substrate base 211 may include a single base layer or may have a structure in which a plurality of base layers are stacked. The substrate base 211 may include at least one material selected from among phenol resin, epoxy resin, and polyimide. The substrate base 211 may include at least one material selected from among Frame Retardant 4 (FR4), tetrafunctional epoxy, polyphenylene ether, epoxy/polyphenylene oxide, bismaleimide triazine (BT), Thermount, cyanate ester, polyimide, and liquid crystal polymer.

The redistribution structure 220 may be disposed on the package substrate 210. The redistribution structure 220 may be a substrate on which the first semiconductor chip 230 and the second semiconductor chip 240 are mounted. According to an embodiment, the redistribution structure 220 may be a redistribution interposer. According to an embodiment, the horizontal width of the redistribution structure 220 may be less than the horizontal width of the package substrate 210. The redistribution structure 220 may include a redistribution insulation layer 221 and a redistribution pattern 223.

The redistribution insulation layer 221 may cover the redistribution pattern 223. The redistribution insulation layer 221 may include a plurality of insulation layers stacked in a vertical direction or may include a single insulation layer. The redistribution insulation layer 221 may include, for example, PID or PSPI.

The redistribution pattern 223 may include a plurality of redistribution lines 2231 extending in a horizontal direction and a plurality of redistribution vias 2233 extending at least partially through the redistribution insulation layer 221. The plurality of redistribution lines 2231 may extend in a horizontal direction along at least one of the top surface and the bottom surface of each of the insulation layers constituting the redistribution insulation layer 221. Here, at least some of the plurality of redistribution lines 2231 may be at a different vertical level from the other redistribution lines 2231. The plurality of redistribution vias 2233 may electrically interconnect to one another the plurality of redistribution lines 2231 that are at different vertical levels.

According to an embodiment, the plurality of redistribution vias 2233 may have a tapered shape such that the horizontal width thereof decreases as the distance from the first semiconductor chip 230 and the second semiconductor chip 240 increases in the vertical direction. This shape may be because the semiconductor package 200 is manufactured in a chip-last method.

The redistribution pattern 223 may include a material that is substantially the same as or similar to the material constituting the redistribution pattern 113 described above with reference to FIG. 1A. The redistribution structure 220 may include a plurality of redistribution pads 225 at the top of the redistribution pattern 223. The plurality of redistribution pads 225 may protrude from the uppermost redistribution insulation layer 221.

A first connection terminal SB1 may be provided between the package substrate 210 and the redistribution structure 220. The first connection terminal SB1 may contact the substrate pad 213 of the package substrate 210 and a redistribution pad 225 of the redistribution structure 220, thereby physically and electrically interconnecting the package substrate 210 to the redistribution structure 220. The first connection terminal SB1 may include, for example, solder.

The first semiconductor chip 230 and the second semiconductor chip 240 may be arranged on the redistribution structure 220. The first semiconductor chip 230 and the second semiconductor chip 240 may each be a memory chip or a logic chip. The memory chip may be, for example, a volatile memory chip like a DRAM or SRAM or a non-volatile memory chip like PRAM, MRAM, FeRAM, or RRAM. Also, the logic chip may be, for example, a microprocessor, an analog device, or a digital signal processor.

The first semiconductor chip 230 and the second semiconductor chip 240 may be semiconductor chips of the same kind or semiconductor chips of different kinds. According to embodiments, the first semiconductor chip 230 and the second semiconductor chip 240 may be logic chips. According to embodiments, one of the first semiconductor chip 230 and the second semiconductor chip 240 may be a logic chip, and the other one may be a memory chip.

The first semiconductor chip 230 may include a first semiconductor substrate 231, a first active layer 233, and a first chip pad 235. The second semiconductor chip 240 may include a second semiconductor substrate 241, a second active layer 243, and a second chip pad 245.

According to an embodiment, at least one of the first semiconductor substrate 231 and the second semiconductor substrate 241 may include silicon. For example, at least one of the first semiconductor substrate 231 and the second semiconductor substrate 241 may include a silicon semiconductor or a compound semiconductor including silicon like silicon-germanium. Since at least one of the first semiconductor substrate 231 and the second semiconductor substrate 241 includes silicon, the at least one of the first semiconductor substrate 231 and the second semiconductor substrate 241 including silicon may be connected to a silicon heat dissipation structure 260 to be described later through silicon-to-silicon direct bonding. The first semiconductor substrate 231 and the second semiconductor substrate 241 may each include a conductive region, e.g., a well doped with impurities. The first semiconductor substrate 231 and the second semiconductor substrate 241 may have various device isolation structures like a STI structure.

The first active layer 233 may be formed on an active surface (not shown) of the first semiconductor substrate 231, and the second active layer 243 may be formed on an active surface (not shown) of the second semiconductor substrate 241. The first active layer 233 and the second active layer 243 may each be substantially the same as or similar to the active layer 123 described with reference to FIG. 1A.

Second connection terminals SB2 may be provided between the first semiconductor chip 230 and the redistribution structure 220 and between the second semiconductor chip 240 and the redistribution structure 220. The second connection terminals SB2 may contact the first chip pad 235 of the first semiconductor chip 230, the second chip pad 245 of the second semiconductor chip 240, and the redistribution pads 225 of the redistribution structure 220, thereby physically and electrically connecting the first semiconductor chip 230 and the second semiconductor chip 240 to the redistribution structure 220. The second connection terminal SB2 may include, for example, at least one of solder, tin (Sn), silver (Ag), copper (Cu), and aluminum (Al).

The molding layer 250 is disposed on the redistribution structure 220 and may cover at least a portion of the first semiconductor chip 230 and at least a portion of the second semiconductor chip 240. According to an embodiment, the top surface of the molding layer 250, the top surface of the first semiconductor chip 230, and the top surface of the second semiconductor chip 240 may be coplanar with one another. The molding layer 250 may include a material that is substantially the same as or similar to the material constituting the molding layer 130 described above with reference to FIG. 1A.

The silicon heat dissipation structure 260 may be disposed on the first semiconductor chip 230 and the second semiconductor chip 240. According to an embodiment, the horizontal width of the silicon heat dissipation structure 260 may be the same as the horizontal width of the redistribution structure 220. Therefore, the silicon heat dissipation structure 260 may also be disposed on the molding layer 130.

According to an embodiment, the silicon heat dissipation structure 260 may be formed by being processed from a bare silicon wafer. According to an embodiment, the thickness of the silicon heat dissipation structure 260 may be from about 10 μm to about 755 μm.

Since the silicon heat dissipation structure 260 includes silicon, as described with reference to FIG. 1B, the silicon heat dissipation structure 260 may be bonded to at least one of the first semiconductor chip 230 and the second semiconductor chip 240 including silicon through silicon-to-silicon direct bonding without a separate adhesive layer. For example, the silicon heat dissipation structure 260 may be bonded to the first semiconductor chip 230 including silicon through silicon-to-silicon direct bonding, but the silicon heat dissipation structure 260 may not be bonded to the second semiconductor chip 240 through silicon-to-silicon direct bonding. Alternatively, the silicon heat dissipation structure 260 may be bonded to both the first semiconductor chip 230 including silicon and the second semiconductor chip 240 including silicon through silicon-to-silicon direct bonding. On the other hand, since the molding layer 250 does not include silicon, the molding layer 250 may not be bonded to the silicon heat dissipation structure 260 through silicon-to-silicon direct bonding.

The semiconductor package 200 according to an embodiment is disposed on the first semiconductor chip 230 and the second semiconductor chip 240 and includes the silicon heat dissipation structure 260 that is bonded to at least one of the first semiconductor chip 230 and the second semiconductor chip 240 through silicon-to-silicon direct bonding. Therefore, as compared to a case where a separate adhesive layer is provided, heat generated due to the operation of at least one of the first semiconductor chip 230 and the second semiconductor chip 240 may be better dissipated. Therefore, heat dissipation characteristics of the semiconductor package 200 may be improved.

FIG. 3B is a cross-sectional view of a semiconductor package 200a according to an embodiment. Since components of the semiconductor package 200a shown in FIG. 3B are similar to the components of the semiconductor package 200 described above with reference to FIG. 3A, descriptions below focus on the differences therebetween.

Referring to FIG. 3B, the semiconductor package 200a may include the package substrate 210, a redistribution structure 220a, the first semiconductor chip 230, the second semiconductor chip 240, the molding layer 250, and the silicon heat dissipation structure 260.

The redistribution structure 220a may be disposed on the package substrate 210. The redistribution structure 220a may be a substrate on which the first semiconductor chip 230 and the second semiconductor chip 240 are mounted. According to an embodiment, the redistribution structure 220a may be a redistribution interposer. According to an embodiment, the horizontal width of the redistribution structure 220a may be less than the horizontal width of the package substrate 210. The redistribution structure 220a may include a redistribution insulation layer 221a and a redistribution pattern 223a.

The redistribution insulation layer 221a may cover the redistribution pattern 223a. The redistribution insulation layer 221a may include a plurality of insulation layers stacked in a vertical direction or may include a single insulation layer. The redistribution insulation layer 221a may include a material that is substantially the same as or similar to the material constituting the redistribution insulation layer 221 described above with reference to FIG. 3A.

The redistribution pattern 223a may include a plurality of redistribution lines 2231a extending in a horizontal direction and a plurality of redistribution vias 2233a extending at least partially through the redistribution insulation layer 221a.

According to an embodiment, the plurality of redistribution vias 2233a may have a tapered shape such that a horizontal width thereof increases as the distance from the top surface of the redistribution structure 220a increases in the vertical direction. This shape may be because the semiconductor package 200a is manufactured in a chip-first method.

The redistribution pattern 223a may include a material that is substantially the same as or similar to the material constituting the redistribution pattern 223 described above with reference to FIG. 3A. The redistribution structure 220a may include a plurality of redistribution pads 225a disposed at the top of the redistribution pattern 223a.

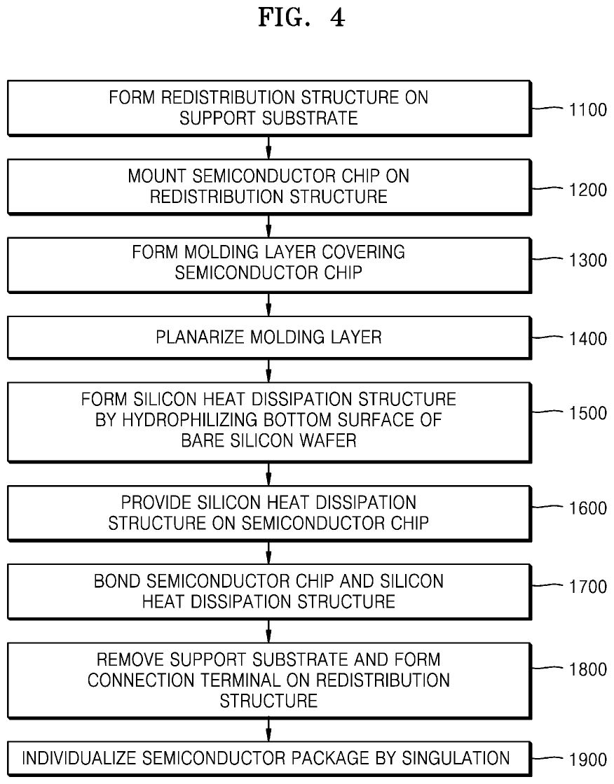

FIG. 4 is a flowchart schematically illustrating a method of manufacturing a semiconductor package, according to embodiments. FIGS. 5A to 5H are cross-sectional views showing respective operations of a method of manufacturing a semiconductor package, according to embodiments.

Referring to FIGS. 4 and 5A, the redistribution structure 110 may be formed on a provided support substrate CS (Step 1100). According to an embodiment, the support substrate CS may be a semiconductor substrate, a glass substrate, a ceramic substrate, or a plastic substrate, but is not limited thereto. The redistribution structure 110 may be formed by forming a redistribution insulation layer 111 through a lamination process and forming a redistribution pattern 113 through a plating process. In detail, the redistribution structure 110 may be formed by repeatedly performing formation of a redistribution line 1131, formation of a via hole (not shown) penetrating through the redistribution insulation layer 111, and formation of a redistribution via 1133 filling the via hole.

Referring to FIGS. 4 and 5B, in a result structure of FIG. 5A, the semiconductor chip 120 may be mounted on the redistribution structure 110 (Step 1200). The semiconductor chip 120 may be mounted on the redistribution structure 110 through the connection terminal SB (refer to FIG. 1A). As the connection terminal SB is coupled to the redistribution pad 115 and the chip pad 125, the semiconductor chip 120 may be fixed on the redistribution structure 110.

Referring to FIGS. 4 and 5C, in a result structure of FIG. 5B, the molding layer 130 covering the semiconductor chip 120 may be formed (Step 1300). The molding layer 130 may be formed to cover the top surface, the bottom surface, and both side surfaces of the semiconductor chip 120.

Referring to FIGS. 4 and 5D, in a result structure of FIG. 5C, the molding layer 130 may be planarized (Step 1400). The planarization may be, for example, a chemical mechanical planarization (CMP) process. As the molding layer 130 is planarized, the top surface of the molding layer 130 may be coplanar with the top surface of the semiconductor chip 120.

Referring to FIGS. 4 and 5E, in a result structure of FIG. 5D, first, one surface of a bare silicon wafer (not shown) may be hydrophilized, and thus, a silicon heat dissipation structure 140 may be formed (Step 1500). Here, the one hydrophilized surface of the bare silicon wafer may be referred to as the bottom surface of the silicon heat dissipation structure 140. According to an embodiment, the bottom surface of the silicon heat dissipation structure 140 may be hydrophilized through plasma treatment using oxygen. Through the hydrophilization, a second water treatment layer WL2 including a Si—OH bond may be formed on the bottom surface of the silicon heat dissipation structure 140. According to an embodiment, an operation of hydrophilizing the top surface of the semiconductor chip 120 may be performed. The hydrophilization may be, for example, plasma treatment using oxygen. Through the hydrophilization, a first water treatment layer WL1 including a Si—OH bond may be formed on the top surface (e.g., inactive surface) of the semiconductor chip 120. According to an embodiment, a preliminary hydrophilization may be further performed before performing the hydrophilization on the bottom surface of the silicon heat dissipation structure 140 and/or the hydrophilization on the top surface of the semiconductor chip 120. The preliminary hydrophilization may be, for example, hydrophilization using deionized water (DI).

Next, the silicon heat dissipation structure 140 having a hydrophilized bottom surface may be provided on the semiconductor chip 120 (Step 1600). The silicon heat dissipation structure 140 may be vertically aligned with the semiconductor chip 120 and overlap with the semiconductor chip 120 in a vertical direction.

Referring to FIGS. 4 and 5F, in a result structure of FIG. 5E, the semiconductor chip 120 and the silicon heat dissipation structure 140 may be bonded to each other (Step 1700). In detail, the semiconductor chip 120 and the silicon heat dissipation structure 140 may be bonded to each other through silicon-to-silicon direct bonding. First, the semiconductor chip 120 having a hydrophilized top surface and the silicon heat dissipation structure 140 having a hydrophilized bottom surface are brought into contact with each other, and then an annealing process may be performed on the semiconductor chip 120 and the silicon heat dissipation structure 140. Through the above-stated process, the Si—OH bond included in the first water treatment layer WL1 on the top surface (e.g., inactive surface) of the semiconductor chip 120 and the Si—OH bond included in the second water treatment layer WL2 on the bottom surface of the silicon heat dissipation structure 140 may react with each other, and thus, the first oxide layer 121O and the second oxide layer 140O having Si—O—Si bonds may be formed. At this time, the semiconductor chip 120 and the silicon heat dissipation structure 140 may be bonded to each other through silicon-to-silicon direct bonding without a separate adhesive layer. Specifically, the silicon-to-silicon direct bonding may include the Si—O—Si bonds. The annealing process may be performed at a certain temperature selected from a range, for example, from about 150° C. to about 400° C., but aspects of the inventive concept are not limited thereto.

Referring to FIGS. 4 and 5G, in a result structure of FIG. 5F, first, the support substrate CS (refer to FIG. 5F) may be removed from the redistribution structure 110 (Step 1800). Next, after a result structure of FIG. 5F from which the support substrate CS is removed is turned upside down such that the redistribution structure 110 is located on top, the external connection terminals OSB may be formed on the redistribution structure 110 (Step 1800). Here, the silicon heat dissipation structure 140 connected to the semiconductor chip 120 may serve as a support substrate.

Referring to FIGS. 4 and 5H, singulation may be performed on a result structure of FIG. 5G. Therefore, the individualized semiconductor package 100 may be manufactured (Step 1900).

Although FIGS. 4 and 5A to 5H show that the redistribution structure 110 is first formed and then the semiconductor chip 120 is mounted on the redistribution structure 110, aspects of the inventive concept are not limited thereto. For example, the semiconductor package 100a shown in FIG. 2 may be manufactured by first mounting the semiconductor chip 120 and then forming the redistribution structure 110.

The semiconductor package 100 according to an embodiment is disposed on the semiconductor chip 120 and includes the silicon heat dissipation structure 140 that is bonded to the semiconductor chip 120 through silicon-to-silicon direct bonding. Therefore, heat generated due to the operation of the semiconductor chip 120 may be better dissipated than a case where a separate adhesive layer is included. Therefore, heat dissipation characteristics of the semiconductor package 100 including the same may be improved. Also, since the silicon heat dissipation structure 140 may serve as a support substrate in the process of manufacturing the semiconductor package 100, an operation of providing a separate support substrate may be omitted. Therefore, the process of manufacturing the semiconductor package 100 may be simplified.

While aspects of the inventive concept have been particularly shown and described with reference to embodiments thereof, it will be understood that various changes in form and details may be made therein without departing from the spirit and scope of the following claims.

1. A semiconductor package comprising:
a redistribution structure including a redistribution pattern and a redistribution insulation layer covering the redistribution pattern;
a semiconductor chip disposed on the redistribution structure and having an active surface and an inactive surface opposite to the active surface;
a molding layer disposed on the redistribution structure and covering at least a portion of the semiconductor chip; and
a silicon heat dissipation structure disposed on the semiconductor chip,
wherein the silicon heat dissipation structure is bonded to the semiconductor chip through silicon (Si)-to-Si direct bonding.

2. The semiconductor package of claim 1, wherein the inactive surface of the semiconductor chip is hydrophilized.

3. The semiconductor package of claim 1, wherein a top surface of the semiconductor chip is coplanar with a top surface of the molding layer.

4. The semiconductor package of claim 1, further comprising a silicon oxide layer provided between the semiconductor chip and the silicon heat dissipation structure.

5. The semiconductor package of claim 1, wherein a horizontal width of the silicon heat dissipation structure is identical to a horizontal width of the redistribution structure.

6. The semiconductor package of claim 1, further comprising an air layer provided between the molding layer and the silicon heat dissipation structure.

7. The semiconductor package of claim 1, wherein the silicon heat dissipation structure is processed from a bare silicon wafer having a hydrophilized surface.

8. The semiconductor package of claim 1, wherein a thickness of the silicon heat dissipation structure is from 10 um to 755 um.

9. The semiconductor package of claim 1, wherein the redistribution structure comprises a redistribution interposer, and
the semiconductor package further comprises a package substrate under the redistribution structure.

10. The semiconductor package of claim 1, wherein the redistribution pattern comprises a redistribution line and a redistribution via, and the redistribution via has a tapered shape that a horizontal width thereof decreases in a vertical direction away from the semiconductor chip.

11. The semiconductor package of claim 1, wherein the redistribution pattern comprises a redistribution line and a redistribution via, and the redistribution via has a tapered shape that a horizontal width thereof increases in a vertical direction away from the semiconductor chip.

12. A semiconductor package comprising:
a package substrate;
a redistribution structure disposed on the package substrate and including a redistribution pattern and a redistribution insulation layer covering the redistribution pattern;
a first semiconductor chip disposed on the redistribution structure and having a first active surface and a first inactive surface opposite to the first active surface;
a second semiconductor chip disposed on the redistribution structure and having a second active surface and a second inactive surface opposite to the second active surface;
a molding layer disposed on the redistribution structure and covering at least a portion of the first semiconductor chip and at least a portion of the second semiconductor chip; and
a silicon heat dissipation structure disposed on the first semiconductor chip and the second semiconductor chip,
wherein the silicon heat dissipation structure is bonded to the first semiconductor chip and the second semiconductor chip through silicon (Si)-to-Si direct bonding.

13. The semiconductor package of claim 12, wherein the first inactive surface of the first semiconductor chip and the second inactive surface of the second semiconductor chip are hydrophilized.

14. The semiconductor package of claim 12, wherein a top surface of the first semiconductor chip, a top surface of the second semiconductor chip, and a top surface of the molding layer are coplanar with one another.

15. The semiconductor package of claim 12, wherein any one of the first semiconductor chip and the second semiconductor chip is a logic chip, and the other one of the first semiconductor chip and the second semiconductor chip is a memory chip.

16. The semiconductor package of claim 12, wherein a horizontal width of the silicon heat dissipation structure is identical to a horizontal width of the redistribution structure.

17. The semiconductor package of claim 12, further comprising:
a silicon oxide layer provided between the first semiconductor chip and the silicon heat dissipation structure and between the second semiconductor chip and the silicon heat dissipation structure; and
an air layer provided between the silicon heat dissipation structure and the molding layer.

18. The semiconductor package of claim 12, wherein the redistribution pattern comprises a redistribution line and a redistribution via, and the redistribution via has a tapered shape that a horizontal width thereof decreases in a vertical direction away from the first and the second semiconductor chip.

19. The semiconductor package of claim 12, wherein the redistribution pattern comprises a redistribution line and a redistribution via, and the redistribution via has a tapered shape that a horizontal width thereof increases in a vertical direction away from the first and the second semiconductor chip.

20. A semiconductor package comprising:
a redistribution structure including a redistribution pattern and a redistribution insulation layer covering the redistribution pattern;
a semiconductor chip disposed on the redistribution structure and having an active surface and an inactive surface opposite to the active surface, wherein the inactive surface is hydrophilized;
a molding layer disposed on the redistribution structure and covering at least a portion of the semiconductor chip; and
a silicon heat dissipation structure disposed on the semiconductor chip,
wherein the silicon heat dissipation structure is bonded to the semiconductor chip through silicon-to-silicon direct bonding.

21-25. (canceled)
